(19) United States
(12) Patent Application Publication
(10) Pub. No.: US 2005/0195023 A1
(43) Pub. Date: Sep. 8, 2005

(54) Method and circuit arrangement for demodulating a digital amplitude-modulated radio signal

(75) Inventor: Admir Alihodzic, Graz (AT)

Correspondence Address: DARBY & DARBY P.C., P. O. BOX 5257, NEW YORK, NY, 10150-5257, US

(73) Assignee: Infineon Technologies AG, Munich (DE)

(21) Appl. No.: 11/084,216

(22) Filed: Mar. 18, 2005

Related U.S. Application Data
(63) Continuation of application No. PCT/DE03/02609, filed on Aug. 4, 2003.

(30) Foreign Application Priority Data
Sep. 24, 2002 (DE) 102 44 450.1

(51) Int. Cl. H03D 1/00

(52) U.S. Cl. 329/347

(57) ABSTRACT

Method and a circuit arrangement for demodulating a digital amplitude-modulated radio signal, received using a reception device, having a carrier signal and a digital information signal impressed thereon. The radio signal is split into first and second signal components having a same polarization and opposite phases, and the first and second signal components are respectively inverted and then “ANDed”.

### CROSS-REFERENCE TO RELATED APPLICATION

This application is a continuation of International Patent Application Serial No. PCT/DE2003/002609, filed Aug. 4, 2003, which published in German on Apr. 8, 2004 as WO 2004/030300, and is incorporated herein by reference in its entirety.

### FIELD OF THE INVENTION

The invention relates to a method and a circuit arrangement for demodulating a digital amplitude-modulated radio signal received using a reception device.

### BACKGROUND OF THE INVENTION

Contactless chip cards, particularly RFID (radio frequency identification) chip cards, use a radio link to receive not just an information signal, comprising an amplitude-modulated radio signal, but also to take the operating voltage required for operating the chip card from the received signal.

As shown in FIG. 1 and described in RFID handbook; Finkenzeller, K.; 2^{nd} Edition, these chip cards meet this objective by having a rectification device which is connected to two outputs of a reception device. In addition, an output of the reception device is supplied to a demodulation device. The latter separates a received carrier signal from the information signal which is contained.

For this purpose, the demodulation device contains an RC element with the task of filtering the carrier frequency out of the received signal. The RC element's dimensions are chosen on the basis of the frequency of the received carrier signal and, its amplitude. This means that the dimensions of the RC element may be large and take up a correspondingly large amount of space and proportion of the area of a chip for the contactless chip card.

FIG. 2 shows a circuit arrangement in which a received signal is digitized, before demodulation by an RC element, using an inverter and two field-effect transistors of complimentary conduction type which are connected to the latter's output.

### SUMMARY OF THE INVENTION

It is an object of the invention to reduce the space and area requirement for the known RC element significantly and hence likewise to reduce the production costs for chips for contactless chip cards.

This object is achieved with a method and a circuit arrangement for carrying out this method, where a digital amplitude-modulated radio signal, received using a reception device, having a carrier signal and a digital information signal impressed thereon is split into first and second signal components with the same polarization and the opposite phase, and the first and second signal components are “ANDed”.

### BRIEF DESCRIPTION OF THE DRAWINGS

The invention is described in more detail below using an exemplary embodiment with reference to the figures, in which:

FIG. 1 shows a circuit arrangement for demodulation based on the prior art;

FIG. 2 shows a circuit arrangement for demodulation; and

FIG. 3 shows a circuit arrangement for demodulation based on the invention.

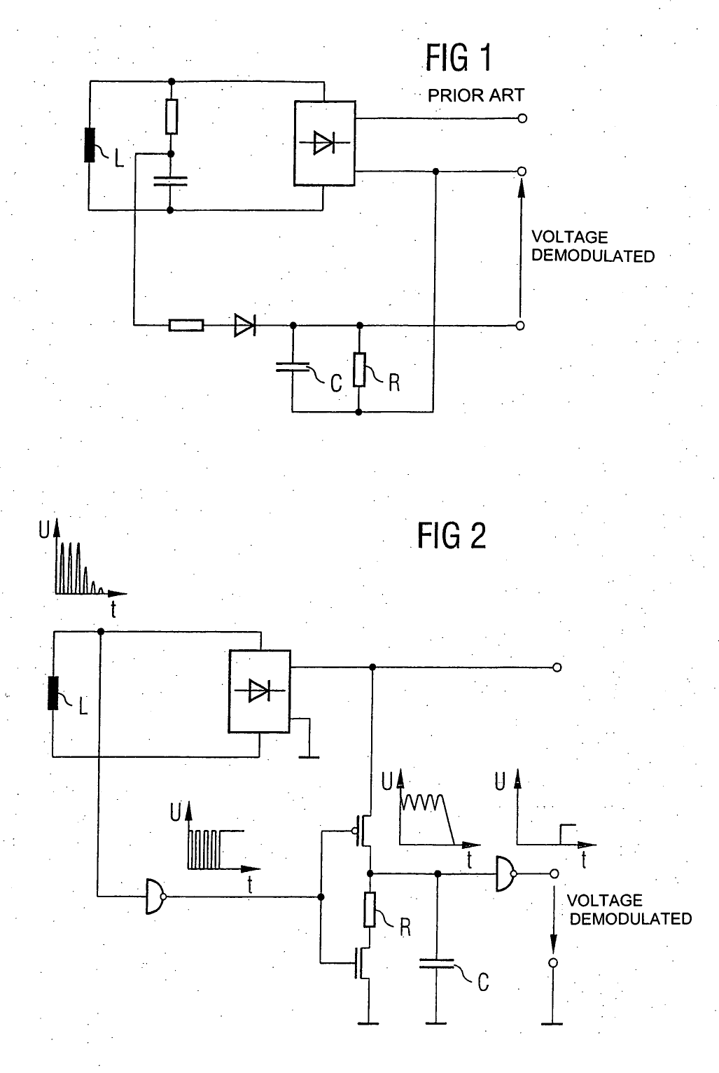

### DETAILED DESCRIPTION OF PREFERRED EMBODIMENTS OF THE INVENTION

In an embodiment of the present invention there is a method and circuit arrangement for carrying out this method, where a digital amplitude-modulated radio signal, received using a reception device, having a carrier signal and a digital information signal impressed thereon is split into first and second signal components with the same polarization and the opposite phase, and the first and second signal components are “ANDed”.

With this method, an RC element for demodulating the received signal is replaced by the AND function. Hence, the demodulation takes place in the AND function, with an RC element in the further signal processing having just a signal-smoothing task. For this purpose, the RC element can be given correspondingly smaller dimensions.

The demodulation by the AND function involves the respective positive half-waves of the received radio signal being taken from both outputs of the reception device simultaneously. Each of these two signal components is supplied independently to an inverter. This inverter changes the analog signal component comprising positive half-waves into a digital square-wave signal. The, amplitude of this square-wave signal assumes only two states in this case, U=U_{MAX} or U=U_{MIN}. As a result of the inversion in the inverter the signal component received has been phase-shifted through 90 degrees with respect to the original signal component.

Like the two signal components of the received radio signal, the digital signal components of the radio signal which are obtained as a result of the inversion are also in antiphase with respect to one another. In line with the invention, the two signal components are supplied to an AND function and are “ANDed” there.

Hence, a digital zero is obtained from the phase-shifted signal components after “ANDing”. Only for received radio signals whose amplitude is zero is a digital one obtained after “ANDing”. As a result, the digital information signal remains at the output of the AND function. This demodulated digital information signal is supplied to an arrangement comprising two field-effect transistors of complimentary conduction type. This brings about amplification of the digital signal.

As a result of the inventive digital and differential demodulation of the received radio signal, slight interference signals having twice the frequency of the received radio signal remain which are superimposed on the information signal. These have a relatively small amplitude. These interference signals need to be filtered out by the known RC element.

The doubled frequency of these interference signals and the small amplitude mean that the capacitive element of the RC element and also the resistive element of the RC element can be given much smaller dimensions.

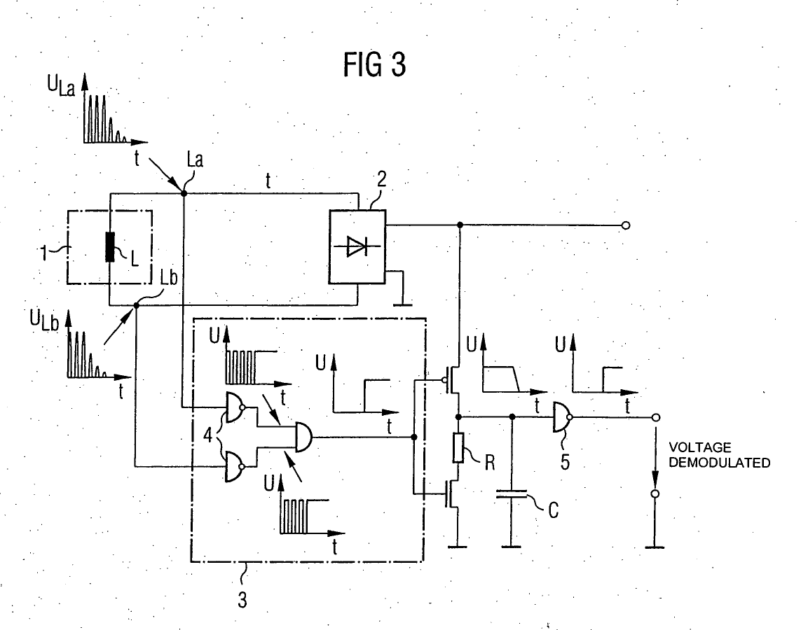

The circuit arrangement in FIG. 3 contains a reception device 1, having a coil L, a rectification unit 2 and a demodulation unit 3. The reception unit 1 receives a radio signal having a predetermined frequency. As a result of induction by means of the radio signal on the coil L, antiphase positively polarized half-waves of the radio signal U_{LA} and U_{LB} appear at the two outputs of the coil L and the reception device 1 LA and LB in conjunction with the rectification unit 2. The negative half-waves of the radio signal are cut by means of the rectification unit 2 in this case.

In line with the invention, the two signal components U_{LA} and U_{LB}, each independently, are supplied to a respective inverter 4. This inverter 4 converts the respective analog signal components into digital square-wave signals having the same frequency, but the inversion and digitization mean that this involves a digital zero being formed for amplitudes below a predetermined limit and a digital one being formed for amplitudes above a predetermined limit.

The two inverted signals are supplied to an AND function, with the result produced at the output of the AND circuit being a one signal only if the amplitude U_{LA} and U_{LB} of the incoming radio signal is below a specific value. This signal from the output of the AND function is supplied to an arrangement comprising two field-effect transistors of complementary conduction type. As a result, the signal which is at the output of the AND circuit is amplified and inverted.

The RC element connected to the field-effect transistors smoothes the remaining interference signals, which have been superimposed on the digital signal with a smaller amplitude than the latter. In this case, the interference signals have a frequency amounting to twice the magnitude of the frequency of the received radio signal, but a significantly smaller amplitude. The RC element can thus be given significantly smaller dimensions than would be required for demodulating the radio signal. An inverter 5 connected downstream of the RC element is used to invert the smoothed digital signal again and to improve the edges of the digital signal.

1. A method for demodulating a digital amplitude-modulated radio signal, received using a reception device, having a carrier signal and a digital information signal impressed thereon, the method comprising the steps of:
splitting the radio signal into first and second signal components having a same polarization and an opposite phase;
inverting the first and second signal components, respectively; and
ANDing the inverted first and second signal components.

2. The method as claimed in claim 1, wherein the reception device is an inductive coupler.

3. The method as claimed in claim 1, wherein the method is used in contactless chip cards.

4. A circuit arrangement for carrying out the method as claimed in claim 1, comprising:
a reception device having a first and a second output connected to a rectification unit;
first and second digital inverters connected to the first and second outputs, respectively; and
an AND function for ANDing outputs of the first and second digital inverters.

5. The circuit arrangement as claimed in claim 4, wherein the reception device is a coil.

6. The circuit arrangement as claimed in claim 4, wherein an output of the AND function is connected to a first and a second field-effect transistor of complimentary conduction types.

7. The circuit arrangement as claimed in claim 4, wherein the circuit arrangement is arranged in a contactless chip card.

8. A circuit arrangement for demodulating a digital amplitude-modulated radio signal, received using a reception device, having a carrier signal and a digital information signal impressed thereon, comprising:
a splitter means for splitting the radio signal into first and second signal components having a same polarization and an opposite phase;
an inverting means for inverting the first and second signal components, respectively; and
an AND component for ANDing the inverted first and second signal components.

9. The circuit arrangement as claimed in claim 8, wherein the reception device is an inductive coupler.

10. The circuit arrangement as claimed in claim 8, wherein the circuit arrangement is arranged in a contactless chip card.

11. A circuit arrangement for demodulating a digital amplitude-modulated radio signal, received using a reception device, having a carrier signal and a digital information signal impressed thereon, comprising:
a splitter which splits the radio signal into first and second signal components having a same polarization and an opposite phase;
first and second inverters which invert the first and second signal components, respectively; and
an AND component for ANDing the inverted first and second signal components.
